(19) United States
(12) Patent Application Publication
(10) Pub. No.: US 2008/0012561 A1
(43) Pub. Date: Jan. 17, 2008

(54) System and method for assessing contrast response linearity for DCE-MRI images

(75) Inventor: Edward A. Ashton, Webster, NY (US)

Correspondence Address: BLANK ROME LLP, 600 NEW HAMPSHIRE AVENUE, N.W., WASHINGTON, DC, 20037, US

(73) Assignee: VirtualScopics, LLC

(21) Appl. No.: 11/783,075

(22) Filed: Apr. 5, 2007

Related U.S. Application Data
(60) Provisional application No. 60/793,710, filed on Apr. 21, 2006.

(51) Int. Cl. G01R 35/00

(52) U.S. Cl. 324/300

(57) ABSTRACT

A phantom has a casing in which vials are arranged, preferably in rows and columns. The vials are filled with solutions of a substance which appears in the imaging modality to be tested. The solutions are of different concentrations; for example, the concentration can increase row by row. The solutions can contain two substances which appear in the imaging modality, in which case the concentration can increase row by row for one and column by column for the other. The phantom can be used to test the linearity of the response of a DCE-MRI or other medical imaging device and to determine whether the fault lies with the coil or the pulse sequence.

### REFERENCE TO RELATED APPLICATION

The present application claims the benefit of U.S. Provisional Patent Application No. 60/793,710, filed Apr. 21, 2006, whose disclosure is hereby incorporated by reference in its entirety into the present application.

### FIELD OF THE INVENTION

The present invention is directed to a system and method in which a phantom is used to assess the linearity of response for a pulse sequence and coil combination for DCE-MRI imaging.

### DESCRIPTION OF RELATED ART

Dynamic contrast enhanced MRI (DCE-MRI) has demonstrated considerable utility in both diagnosing and evaluating the progression and response to treatment of malignant tumors. By making use of a two-compartment model, with one compartment representing blood and the other abnormal extra-vascular extra-cellular space (EES), the observed uptake curves in tissue and blood can be used to estimate various physiological parameters.

However, DCE-MRI can introduce errors caused by nonlinearity and more particularly by a strong spatial variability in the coil sensitivity. That is a common problem with phased array and composite coils. That level of spatial variability renders the subject data obtained using that system extremely suspect, since a small difference in subject positioning could result in a large change in apparent enhancement. Moreover, the relationship between the observed arterial input function and the tumor enhancement is strongly affected by the relative locations of the tumor and source artery. For the above reasons, some studies have yielded physiologically impossible and highly inconsistent arterial input functions.

Such problems may originate with the pulse sequence, the receiving coil, or both. The state of the art does not allow a determination of the source of the problem.

### SUMMARY OF THE INVENTION

It will be seen from the above that a need exists in the art for a technique for locating the source of such problems.

It is therefore an object of the invention to provide such a technique.

It is another object of the invention to provide a phantom for use in such a technique.

It is still another object of the invention to provide such a phantom which has additional utility.

To achieve the above and other objects, the present invention is directed to a phantom comprising a casing in which vials are arranged, preferably in rows and columns. The vials are filled with solutions of a substance which appears in the imaging modality to be tested. The solutions are of different concentrations; for example, the concentration can increase row by row. The solutions can contain two substances which appear in the imaging modality, in which case the concentration can increase row by row for one and column by column for the other.

The present invention is further directed to a technique for using such a phantom. In such a technique, the phantom is scanned multiple times to determine where the fault lies. For instance, the phantom can be scanned with two coils. If only one of the coils provides erroneous signals, that coil is deemed to be at fault. If both coils provide erroneous readings, the pulse sequence can be changed.

An investigation showing another practical utility of the present invention will now be described.

It is commonly assumed that precise tracking of changes in vascular parameters measurable using DCE-MRI, such as the volume transfer constant (K^{trans}), requires conversion of the observed signal intensity changes seen in various tissues post-injection to tracer concentration values. That conversion process relies on the accurate mapping of T1 relaxation times for the region of interest, and the subsequent registration of the T1 mapping data to the dynamic scans. Both those steps have the potential to introduce significant noise into the parameter estimation process.

There are two primary reasons for making use of conversion to tracer concentration: first, it is assumed that the relationship between signal change and tracer concentration is significantly non-linear; second, it is assumed that the observed signal change will vary significantly depending on the initial T1 of the tissue in question.

It was the goal of that work to demonstrate that use of the proper image acquisition and analysis techniques renders that process unnecessary, allowing a simplified and more robust parameter estimation process. It should be noted that that analysis applies only to the common case where the parameter of interest is relative change in K^{trans} over time.

That work calls into question the necessity of converting signal intensity information directly into tracer concentration values in order to calculate vascular perfusion parameters using a standard two compartment model for the vascular bed. It is generally assumed that that is necessary, although that question has not been directly addressed in the literature for the case where signal changes are defined as difference from baseline. We make use of phantom data with multiple known base T1 values and tracer concentrations to simulate various tissue uptake curves. Values for the volume transfer constant K^{trans} are then calculated using three methods: signal with baseline subtracted; signal converted to apparent tracer concentration; and known ideal tracer concentration. Correlation between ideal and calculated K^{trans} values is found to be marginally higher for signal with baseline subtracted (0.91) than for signal converted to apparent tracer concentration (0.88).

### BRIEF DESCRIPTION OF THE DRAWINGS

A preferred embodiment of the invention and various experimentally verified uses for it will be disclosed in detail with respect to the drawings, in which:

FIG. 1 shows once slice from an image of the phantom according to the preferred embodiment;

FIG. 2 shows an expected relationship between gadolinium concentration and signal delta;

FIG. 3 shows an observed relationship between the gadolinium concentration and signal delta for a particular sequence and coil;

FIG. 4 shows an observed relationship between gadolinium concentration and signal delta for the same sequence and a body coil;

FIG. 5 shows a flow chart of the use of the phantom of FIG. 1 in testing equipment;

FIG. 6A is an image of a phantom without gadolinium added;

FIG. 6B is an image of a phantom with gadolinium added;

FIG. 7A is a scatterplot of nominal Gd concentration (mM) vs. signal baseline;

FIG. 7B is a scatterplot of calculated Gd concentration;

FIG. 8A is a plot of ideal tissue uptake curves;

FIG. 8B is a plot of ideal arterial input function;

FIG. 9 is a plot of signal change curves at baseline T1=1016 ms;

FIG. 10 is a plot of estimated tracer concentration curves at baseline T1=1016 ms;

FIG. 11 is a scatterplot of K^{trans} values calculated using signal intensity converted to apparent tracer concentration vs. those calculated using the nominal tracer concentrations; and

FIG. 12 is a scatterplot of K^{trans} values calculated using signal intensity minus baseline vs. those calculated using the nominal tracer concentrations.

### DETAILED DESCRIPTION OF THE PREFERRED EMBODIMENT

A preferred embodiment of the invention will now be set forth in detail with reference to the drawings.

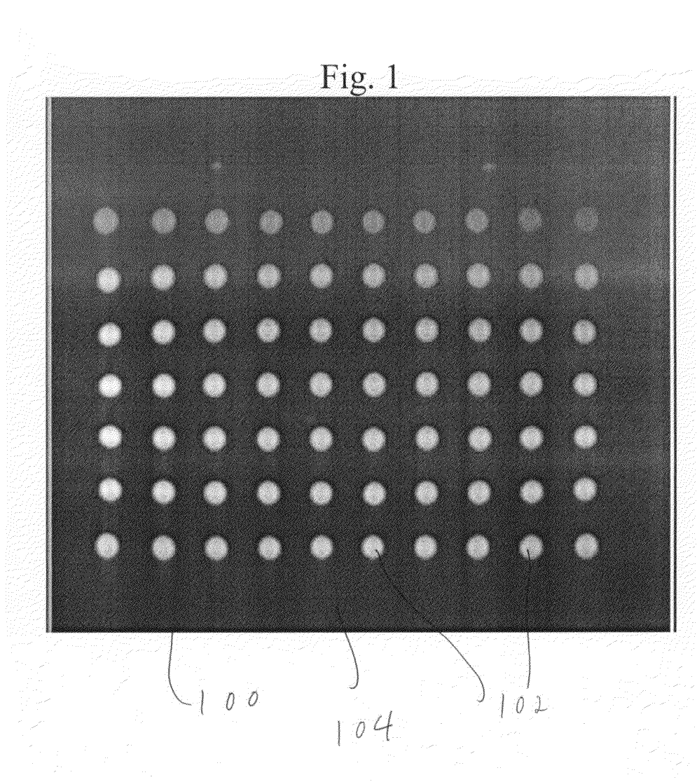

FIG. 1 shows one slice from a body coil perfusion run of a phantom 100 according to the preferred embodiment. As can be seen in FIG. 1, the phantom includes 70 vials 102 arranged in seven rows of 10 vials each, enclosed in a plastic casing 104. In each of the seven rows, the vials 102 contain a different concentration of copper sulfate, yielding native T1 values at 1.5T ranging from 98 ms to 1016 ms. In addition, the vials in each of the 10 columns contain a different concentration of gadolinium, ranging from 0 to 0.9 mM.

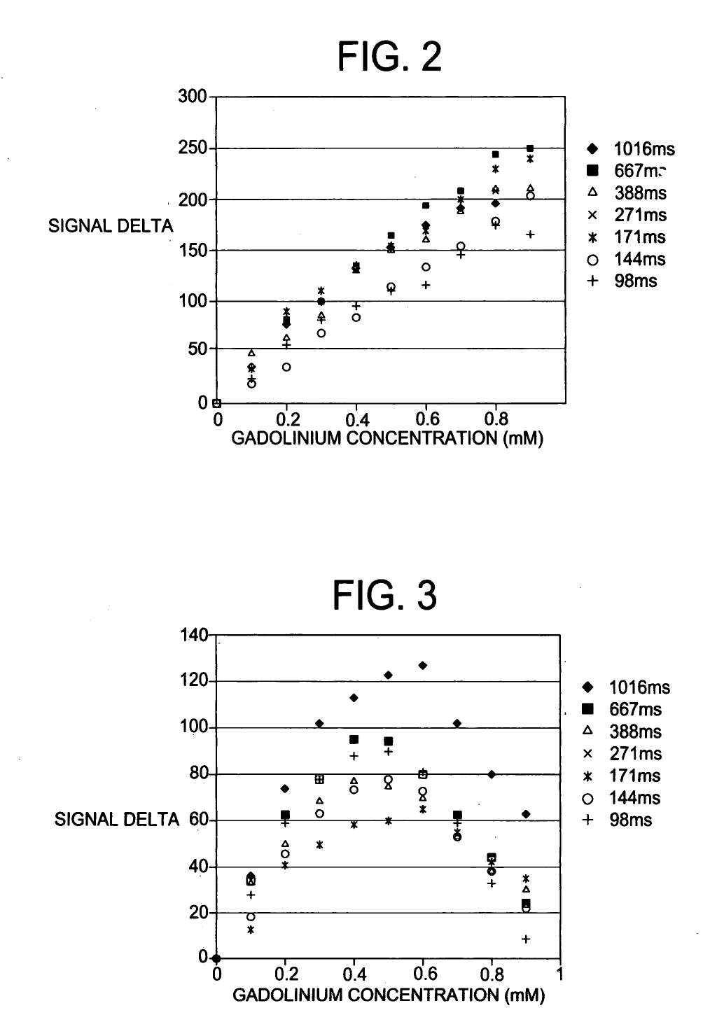

The phantom 100 was used to determine the relationship between changes in gadolinium concentration at different native T1 values and observed signal intensity changes for the perfusion sequence and receiver coil being used. The expected result is shown in FIG. 2, which was derived from data obtained using the standard VirtualScopics perfusion sequence on a GE scanner using a body coil. The relationship is approximately linear, and the dependence on native T1 is minimal.

The results from the site using the matrix coil are given FIG. 3. The relationship is not only non-linear, but is in fact non-monotonic. Moreover, there is apparently a heavy dependence on native T1.

The non-monotonic relationship between signal delta and gadolinium concentration is most likely due to strong spatial variability in the coil sensitivity. That is a common problem with phased array and composite coils. That level of spatial variability renders the subject data obtained using that system extremely suspect, since a small difference in subject positioning could result in a large change in apparent enhancement. Moreover, the relationship between the observed arterial input function and the tumor enhancement will be strongly affected by the relative locations of the tumor and source artery.

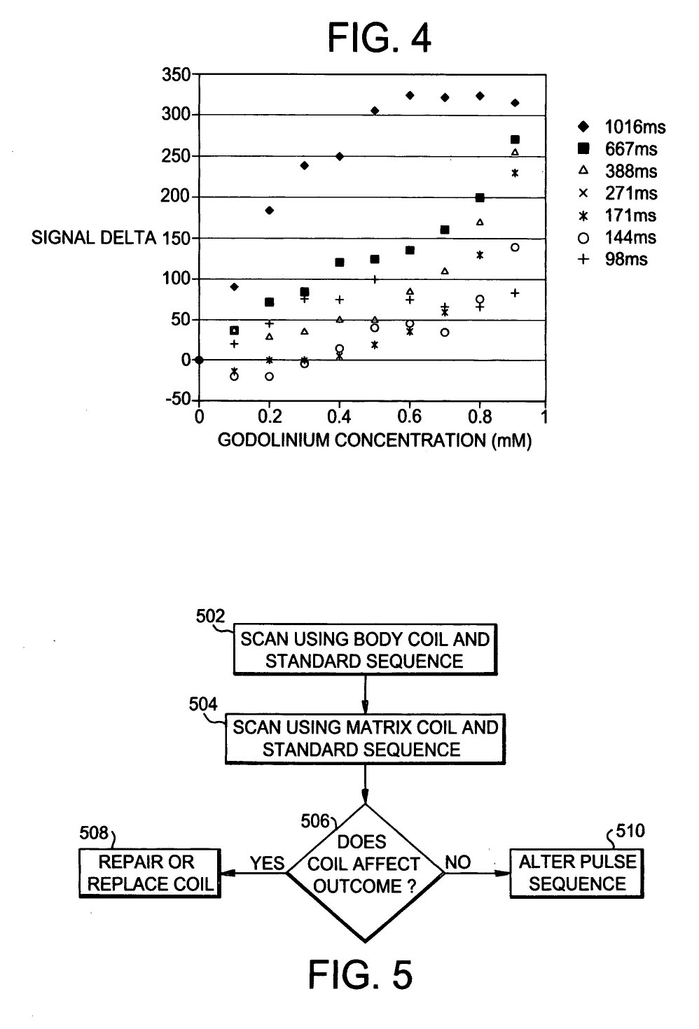

The results from the site using the body coil are given in FIG. 4. Note that the relationship is generally monotonic, but is highly non-linear. Moreover, there is a very heavy dependence on native T1.

Those results are somewhat more surprising, and indicate that switching to a body coil will not be sufficient to provide reliable data. The problems seen in the results have two possible sources: the pulse sequence used and the receiving coil.

To locate the source of the problem, the phantom can be used as shown in the flow chart of FIG. 5. The phantom is scanned, using first the body coil in step 502 and then the matrix coil in step 504, using a standard perfusion sequence. If similarly poor results are obtained with the matrix coil, as determined in step 506, that will indicate that the problem lies in the body coil, which may need to be serviced or replaced in step 508. If good results are obtained with the matrix coil, we may wish to consider altering the pulse sequence used for the perfusion studies in step 510.

Another use for the phantom according to the preferred embodiment will now be explained.

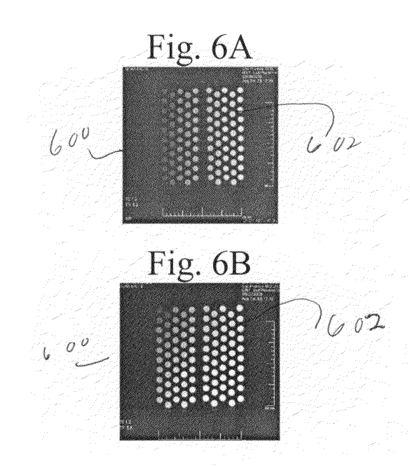

In order to test the relative accuracy and precision of K^{trans} measurements with and without conversion of signal intensity to tracer concentration, a modified version of the phantom was developed, each containing 100 vials in a 10×10 grid. FIGS. 6A and 6B show sample images of the phantoms 600, including the vials 602, without gadolinium added and with gadolinium added, respectively. Each column in both phantoms was filled with a different concentration of a copper sulfate solution, yielding base T1 relaxation times ranging from 98 ms to 1016 ms at 1.5T field strength. Subsequently, different volumes of gadolinium were added to each row of the second phantom, yielding concentrations ranging from 0 to 0.9 mM.

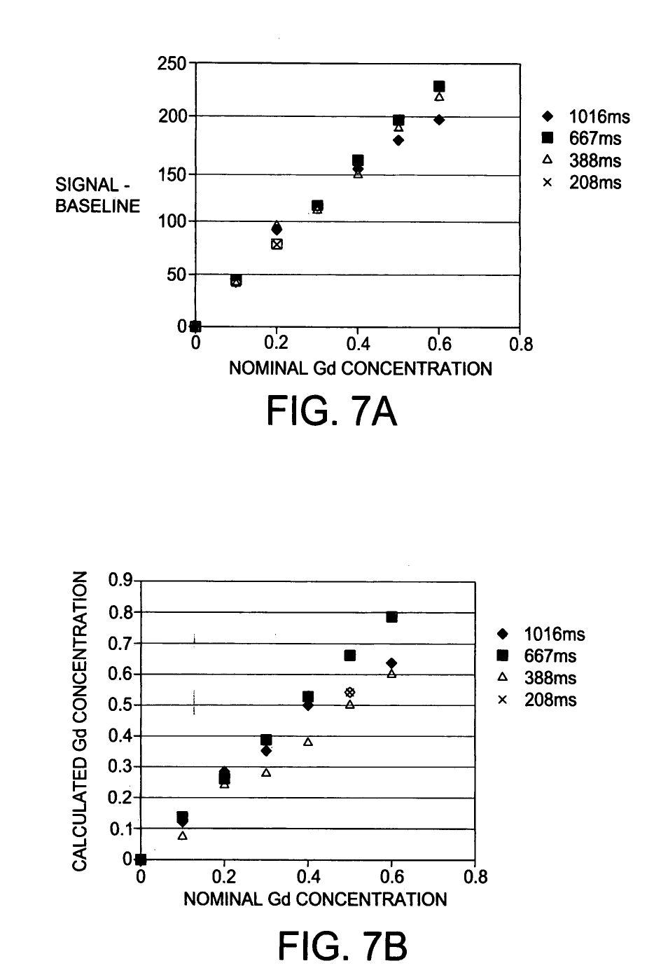

A preliminary idea of the quality of data likely to result from parameter calculation using signal intensity information can be obtained by directly examining the relationship between signal intensity changes and nominal Gd concentration changes. Scatterplots of nominal Gd concentration vs. signal with baseline subtracted, and calculated Gd concentration are given in FIGS. 7A and 7B, respectively. Note that both methods show a roughly linear relationship with Gd concentration.

It should also be noted that the scatter seen in the data is actually higher in the converted tracer concentration data than in the signal intensity data. That may at first seem counter-intuitive. However, that is in fact a predictable result of the fact that noise is introduced into the data through both the T1 mapping and the registration processes needed to produce the converted data.

In clinical trials using human subjects, T1 maps are most frequently generated by scanning the subject using multiple flip angles, and then fitting the resulting signal intensity values at each pixel to a standard signal formation model. In that work, we made use of multiple inversion time T1 measurement. Five sequences were used, with TI/TR of 1.65/1.88, 0.65/0.88, 0.35/0.58, 0.15/0.38, and 0.027/0.260. T1 relaxation times were calculated using the following signal formation model:

$$S = ρ [ 1.0 - A {e}^{\frac{- {T}_{I}}{T 1}} + {e}^{\frac{- {T}_{R}}{T 1}} ] \qquad ( 1 )$$

where S is the observed signal intensity, σ is the spin density, A is a proportionality constant, and T₁ and T_{R} are the inversion and repetition times, respectively. That method is generally considered to be both more accurate and more stable than T1 measurement using multiple flip angles. However, the scan time requirements of that technique make it impractical for use in vivo in regions such as the abdomen and chest, which cannot be immobilized for long periods of time. That experiment, therefore, is something of an ideal case for T1 mapping and calculation of tracer concentrations.

Both phantoms were scanned using a dynamic acquisition sequence. A 3D SPGR sequence was used, with a flip angle of 30 degrees, TR/TE of 5.6/1.2, a 256×160 matrix, and an 8 slice, 64 mm slab. Twenty phases were acquired in 3:38, yielding a temporal resolution of 10.9 s.

Those data allowed the construction of simulated uptake curves with various base T1 values and rates of increase for either tracer concentration or observed signal intensity. Those simulated curves were then used to calculate K^{trans} values, using a scaled model arterial input function. Moreover, because the true molar concentrations of gadolinium in each vial were known, it was also possible to calculate a ground truth or ideal K^{trans} value for each simulated uptake curve.

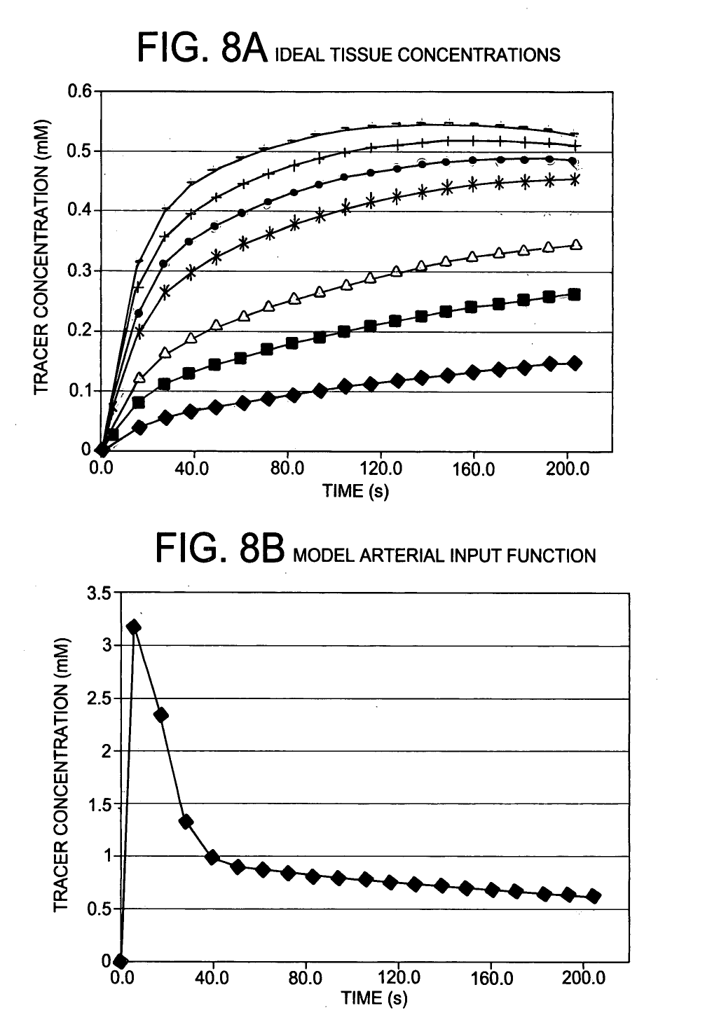

Simulated uptake curves were generated using four different base T1 values: 208 ms, 388 ms, 667 ms, and 1016 ms. That was done in order to address the question of dependence on base T1 when using signal intensity changes to calculate K^{trans}. In addition, 8 different ideal tissue uptake curves were used, with peak concentrations ranging from 0.1 mM to 0.6 mM. That spans the range of concentrations that would be expected in solid tumors in humans, assuming a 0.1 mmol/kg injection of a gadolinium labeled tracer such as gadopentetate dimeglumine. Ideal tissue and AIF curves are shown in FIGS. 8A and 8B, respectively.

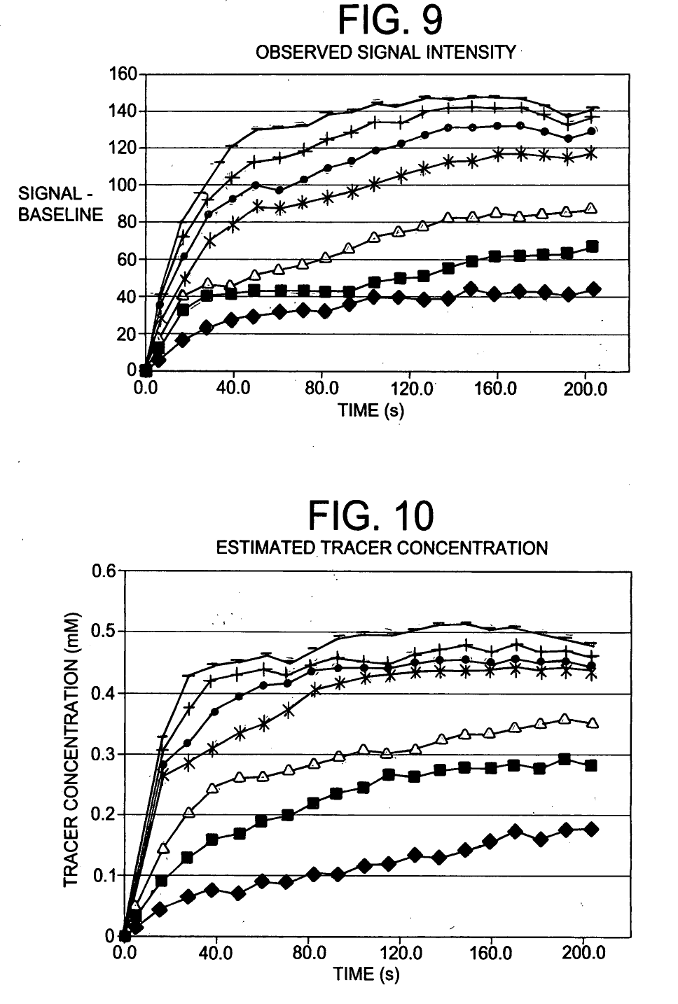

Corresponding signal based uptake curves were generated for each of the 8 ideal tissue uptake curves at each of the 4 base T1 values. Signal curves were generated by interpolating at each time point between the signals observed in the vials with known tracer concentrations above and below the ideal tracer concentration at the appropriate baseline T1 value. Signal curves for the 8 ideal tissue uptake curves with baseline T1=1016 ms are shown in FIG. 9. Corresponding estimated tracer concentration curves, also for baseline T1=1016 ms, are shown in FIG. 10.

K^{trans} values were calculated in three ways: (1) using the known nominal gadolinium concentration values; (2) using gadolinium concentration values derived from apparent signal changes in the dynamic data; (3) using apparent signal change, defined as S(t)-S(0). K^{trans} values derived from the nominal gadolinium concentration were treated as the gold standard. Results for the other methods were evaluated based on their correspondence to those ideal values.

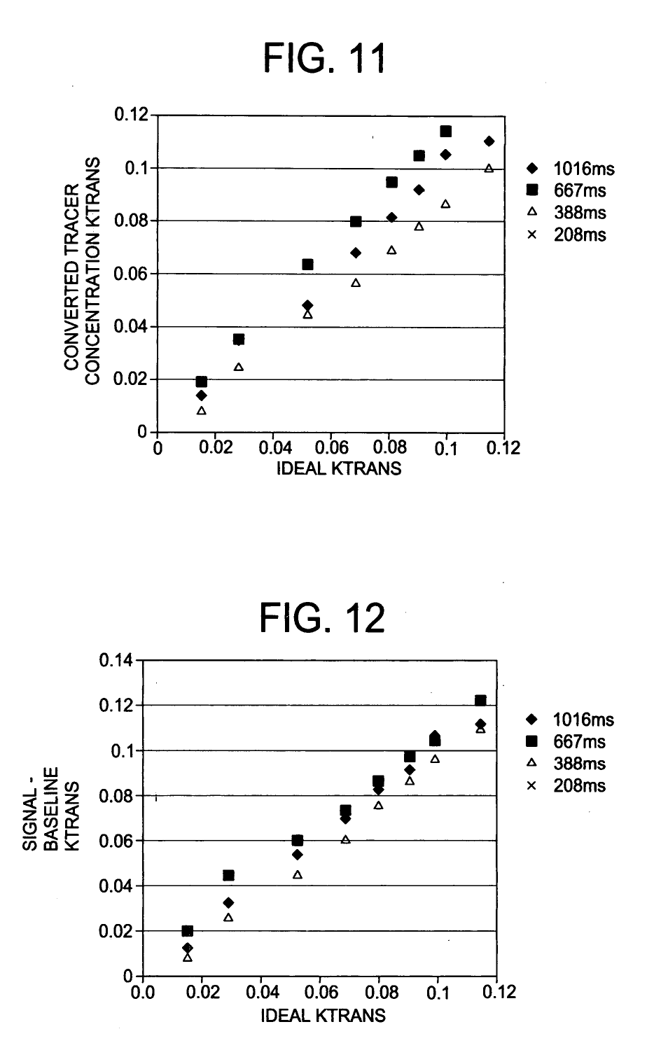

FIG. 11 shows the results for parameters calculated using data converted to apparent tracer concentration values. Note that there is clearly a small dependence on baseline T1, presumably due to some inaccuracy in either the estimation of the baseline T1 value or the registration of the phantom without gadolinium to the phantom with gadolinium. However, the relationship between the calculated and ideal values is more or less linear. Note also that that was something of an ideal case for that process, because there was no need to consider motion and the co-registration between the T1 map and the dynamic data was therefore better than would be expected in vivo. The coefficient of correlation between ideal and estimated values in that case was 0.88. FIG. 12 shows the results for parameters calculated using signal intensity change defined as S(t)-S(0). Note that the apparent dependence on the baseline T1 value in that case is actually less than that in FIG. 11, and that the relationship between ideal and calculated K^{trans} values is similarly linear. The coefficient of correlation between ideal and calculated K^{trans} values in that case was 0.91.

Those results demonstrate that, for the tracer concentrations and base T1 values that are commonly seen in solid tumors and for a variety of tracer uptake rates, conversion from signal intensity to apparent tracer concentration is likely to increase, rather than decrease, the measurement noise in the estimation of kinetic parameters such as K^{trans}. Moreover, that added noise is likely to be greater than that shown here in vivo, due to subject motion which may complicate and corrupt the co-registration of the T1 map and dynamic data.

It is important when determining the proper method to use for a particular application to consider the differential penalty paid for loss of either precision or accuracy. In that experiment there is no apparent bias introduced through the use of raw signal intensity values in the estimation of K^{trans}. However, that lack of bias is dependent upon appropriate scaling of the arterial input function, which may not always be possible. If the scaling is not done with great care, some bias in the measurement is likely to be introduced. Therefore, in the case where an absolute value of K^{trans} in units of 1/min is required, conversion to tracer concentration is necessary.

It should be noted, however, that that is not generally the case. K^{trans} has no absolute defined biological meaning. It is a composite parameter made up of flow and vascular permeability in some unknown ratio. For that reason, the most common use of that parameter is as a marker for change in tumor vascularity induced by either disease progression or response to treatment. For those types of applications, the primary parameter of interest is not the absolute value of K^{trans} at a particular time point, but rather the percentage change in that parameter over time. Absolute accuracy is therefore less important, while precision is much more so. The results of that work indicate that in cases where the primary goal is the tracking of vascular changes over time, calculating K^{trans} using change in signal intensity rather than tracer concentration provides the optimal solution.

While a preferred embodiment and various uses have been set forth above, those skilled in the art who have reviewed the present disclosure will readily appreciate that other embodiments can be realized within the scope of the invention. For example, disclosures of numerical quantities, specific substances, and imaging modalities are illustrative rather than limiting. Also, other arrays of vials can be used, such as three-dimensional arrays. Therefore, the present invention should be construed as limited only by the appended claims.

What is claimed is:

1. A phantom for use with an imaging modality, the phantom comprising:
a plurality of vials;
a casing for holding the plurality of vials; and
a material contained in at least some of the plurality of vials, the material being visible to the imaging modality, the material being contained in said at least some of the plurality of vials in varying concentrations.

2. The phantom of claim 1, wherein the material is contained in said at least some of the plurality of vials as a solution.

3. The phantom of claim 1, wherein the vials are arranged in a two-dimensional array.

4. The phantom of claim 3, wherein the two-dimensional array defines a plurality of rows and a plurality of columns.

5. The phantom of claim 4, wherein the material is contained in the vials in different concentrations in different ones of the rows.

6. The phantom of claim 5, further comprising a second material contained in said at least some of the plurality of vials, the second material being visible to the imaging modality, the second material being contained in said at least some of the plurality of vials in varying concentrations.

7. The phantom of claim 6, wherein the second material is contained in the vials in different concentrations in different ones of the columns.

8. A method for testing an imaging device to locate a source of an error in the imaging device, the method comprising:
(a) providing a phantom for use with an imaging modality used by the imaging device, the phantom comprising a plurality of vials, a casing for holding the plurality of vials, and a material contained in at least some of the plurality of vials, the material being visible to the imaging modality, the material being contained in said at least some of the plurality of vials in varying concentrations;
(b) imaging the phantom in the imaging device to take imaging data; and
(c) locating the source of the error from the imaging data.

9. The method of claim 8, wherein the imaging device can be used with a plurality of receiving coils, and wherein step (b) comprises taking the imaging data with at least two of the receiving coils.

10. The method of claim 9, wherein step (c) comprises:
(i) if the error occurs with only one of the at least two receiving coils, locating the source of the error in said one of the at least two receiving coils; and
(ii) if the error occurs with both or all of the at least two receiving coils, locating the source of the error outside of any of the receiving coils.

11. The method of claim 10, wherein the imaging device uses a pulse sequence, and wherein step (c) (ii) comprises locating the source of the error in the pulse sequence.

12. A method for simulating a medical image of a region of interest in a living body, the method comprising:
(a) providing a phantom for use with an imaging modality, the phantom comprising a plurality of vials, a casing for holding the plurality of vials, and a material contained in at least some of the plurality of vials, the material being visible to the imaging modality, the material being contained in said at least some of the plurality of vials in varying concentrations;
(b) imaging the phantom in the imaging device to take imaging data; and
(c) simulating the medical image from the imaging data.
